(19) United States
(12) Patent Application Publication
(10) Pub. No.: US 2025/0021004 A1
(43) Pub. Date: Jan. 16, 2025

(54) ION IMPLANTATION THICK FILM RESIST COMPOSITION, A METHOD FOR MANUFACTURING A PROCESSED SUBSTRATE USING THE SAME, AND A METHOD FOR MANUFACTURING A DEVICE USING THE SAME

(71) Applicant: MERCK ELECTRONICS LTD., TOKYO (JP)

(72) Inventors: TETSUMASA TAKAICHI, SHIZUOKA (JP); HIROSHI YANAGITA, SHIZUOKA (JP); MASATO SUZUKI, SHIZUOKA (JP)

(21) Appl. No.: 18/821,999

(22) Filed: Aug. 30, 2024

Related U.S. Application Data
(63) Continuation of application No. PCT/EP2023/054781, filed on Feb. 27, 2023.

(30) Foreign Application Priority Data
Mar. 1, 2022 (JP) 2022-031158

(51) Int. Cl. G03F 7/039; C08F 212/14; C23C 14/04; C23C 14/48; G03F 7/004; G03F 7/40; H01L 21/266; H01L 21/768

(52) U.S. Cl. CPC G03F 7/0397; C08F 212/24; C23C 14/042; C23C 14/48; G03F 7/0045; G03F 7/40; C08F 2800/10; H01L 21/266; H01L 21/768

(57) ABSTRACT

An ion implantation thick film resist composition includes a polymer (A) as defined herein, a photoacid generator (B) and a solvent (C), wherein the film thickness of the resist film formed from the composition is 1.0 to 50 μm; and the mass average molecular weight of the polymer (A) is 5,000 to 19,000.

### CROSS-REFERENCE TO RELATED APPLICATIONS

This application is a Continuation under 35 USC § 111(a) of International Patent Application No. PCT/EP2023/054781, filed Feb. 27, 2023, which claims priority to the Foreign Application No. JP2022-031158 filed on Mar. 1, 2022. The entire contents of these applications are incorporated herein by reference in their entirety.

### BACKGROUND OF THE INVENTION

### Technical Field

The present invention relates to an ion implantation thick film resist composition, a method for manufacturing a processed substrate using the same and a method for manufacturing a device using the same.

### Background of the Invention

In the manufacture of semiconductor devices, an ion implantation process is employed in which impurity ions are introduced into a semiconductor substrate using a resist pattern as a mask. The impurity ions are implanted at high energy using an ion implanter. As designs become finer and the amount of ion implantation tend to increase, resist patterns used in the ion implantation process are required to be thicker and more rectangular, and to have higher heat resistance, or the like.

Thick film resist compositions have been proposed for processes such as plating processes, etching processes. JP 2007-206425 A provides an example of such. However, there is still a demand for improved resolution and rectangularity.

Although thick film resist compositions have been proposed for high-energy ion implantation processes and the like, improvements in resolution and the like are still required as exemplified by the teachings of WO 2004/104702, for example.

### SUMMARY OF THE INVENTION

The present inventors have considered that there are still one or more problems with ion implantation resist compositions and their uses that require improvement. They include, for example, the following: a resist pattern having sufficiently high rectangularity cannot be obtained; sufficient resolution cannot be obtained; ion implantation resistance of the resist pattern is insufficient; transmittance of the resist film is low; a resist pattern with a high aspect ratio cannot be formed; and heat resistance of the resist pattern is insufficient.

The present invention has been made based on the technical background as described above, and provides an ion implantation thick film resist composition and a method for manufacturing a processed substrate using the same.

The ion implantation thick film resist composition according to the present invention is able to form a resist film having a thickness of 1.0 to 50 μm, and the composition comprises a polymer (A), a photoacid generator (B) and a solvent (C),
wherein,
the mass average molecular weight of the polymer (A) is 5,000 to 19,000; and
the polymer (A) comprises at least one of the repeating units represented by formulae (A-1), (A-2), (A-3) and (A-4):

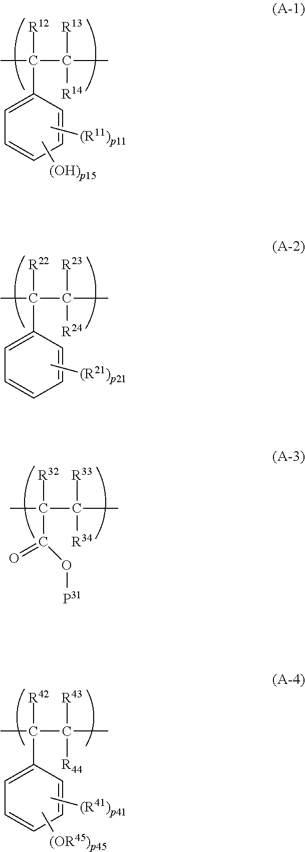

R¹¹, R²¹, R⁴¹ and R⁴⁵ are each independently C₁₋₅ alkyl, wherein methylene in the alkyl can be replaced with oxy;
R¹², R¹³, R¹⁴, R²², R²³, R²⁴, R³², R³³, R³⁴, R⁴², R⁴³ and R⁴⁴ are each independently hydrogen, C₁₋₅ alkyl, C₁₋₅ alkoxy or —COOH;
p11 is 0 to 4, p15 is 1 to 2, and p11+p15≤5;
p21 is 0 to 5;
p41 is 0 to 4, p45 is 1 to 2, and p41+p45≤5;
P31 is C₄₋₂₀ alkyl, wherein a part or all of the alkyl can form a ring, a part or all of H in the alkyl can be replaced with halogen, and methylene in the alkyl can be replaced with oxy or carbonyl.

The method for manufacturing a processed substrate according to the present invention comprises the following steps:
manufacturing a resist pattern using the above-described ion implantation thick film resist composition; and
performing an ion implantation using the resist pattern as a mask, or
processing the underlayer of the resist pattern using the resist pattern as a mask to form a underlayer pattern, and performing an ion implantation using the underlayer pattern as a mask.

The method for manufacturing a device according to the present invention comprises the above-described method for manufacturing a processed substrate.

### Effects of the Invention

The inventors have considered as follows in the course of reaching the present invention. A thick resist film must be formed because the resist pattern itself, which is a mask, is also shaved by the implantation of ionized impurities. In order to form a thick film, the film must have high transparency. A thicker film requires higher rectangularity. Furthermore, since the ion implantation resist pattern generates heat during the process, it must also have excellent heat resistance. As a result of intensive studies, the present inventors have obtained the composition of the present invention. According to the present invention, one or more of the following effects are provided:

A resist pattern with high rectangularity is obtained; a resist film with high resolution is obtained; a resist pattern has high resistance to ion implantation; transmittance of the resist film is high; a resist pattern with high aspect ratio is formed; and heat resistance of the resist pattern is high.

### BRIEF DESCRIPTION OF THE DRAWINGS

FIG. 1 is a schematic view showing the cross-sectional shape of a trench pattern.

FIG. 2 is a schematic view showing cross-sectional shapes of resist patterns having different Wt/Wb ratios as defined herein.

### DETAILED DESCRIPTION OF THE INVENTION

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species. “And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (for example, methyl, ethyl, propyl, butyl, pentyl, hexyl).

When polymer has a plural types of repeating units, these repeating units copolymerize. These copolymerization can be any of alternating copolymerization, random copolymerization, block copolymerization, graft copolymerization, or a mixture thereof. When polymer or resin is represented by a structural formula, n, m or the like that is attached next to parentheses indicate the number of repetitions.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (C) or another component.

Hereinafter, embodiments of the present invention are described in detail.

### Ion Implantation Thick Film Resist Composition

The ion implantation thick film resist composition according to the present invention (hereinafter referred to as the composition) comprises a polymer (A) having a certain structure, a photoacid generator (B) and a solvent (C).

The composition according to the present invention is a thin film resist composition. In the present invention, the thin film means a film having a thickness of 1.0 to 50 μm, preferably 1.2 to 30 μm (more preferably 1.5 to 20 μm; further preferably 2 to 10 am). The viscosity of the composition according to the present invention is preferably 10 to 1,000 mPa·s, more preferably 12 to 500 mPa·s. The viscosity is measured at 25° C. with a capillary viscometer.

The composition according to the present invention is more preferably a KrF chemically amplified resist composition; more preferably a KrF positive type chemically amplified resist composition.

### Polymer (A)

The composition according to the present invention comprises a polymer (A). The polymer (A) comprises at least one of the repeating units represented by the following formulae (A-1), (A-2), (A-3) and (A-4). The polymer (A) reacts with an acid to increase its solubility in an alkaline aqueous solution. This kind of polymer has, for example, an acid group protected by a protecting group, and when an acid is added from outside, the protecting group is eliminated and the solubility in an alkaline aqueous solution increases.

The formula (A-1) is as follows:

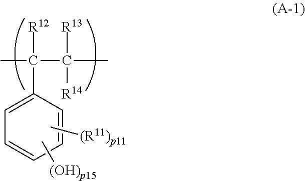

wherein
R¹ is each independently C₁₋₅ alkyl (wherein methylene in the alkyl can be replaced with oxy); preferably methyl or ethyl; more preferably methyl. In the present invention, the expression “methylene in the alkyl can be replaced by oxy” means that oxy can be present between carbon atoms in the alkyl, and it is not intended that the terminal carbon in the alkyl becomes oxy, i.e., have alkoxy or hydroxy.
R¹², R¹³ and R¹⁴ are each independently hydrogen, C₁₋₅ alkyl, C₁₋₅ alkoxy or —COOH; preferably hydrogen or methyl; more preferably hydrogen.
p11 is 0 to 4; preferably 0 or 1; more preferably 0.
p15 is 1 to 2; preferably 1.
p11+p15≤5 is satisfied.

The polymer (A) can contain a plurality of types of repeating units represented by the formula (A-1). For example, it is possible for the polymer to have a structural unit of p15=1 and a structural unit of p15=2 at a ratio of 1:1. In this case, it becomes p15=1.5 as a whole. Hereinafter, unless otherwise specified, the same applies to the numbers for representing polymer in the present invention.

An exemplified embodiment of the formula (A-1) includes the following:

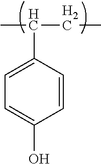

The formula (A-2) is as follows:

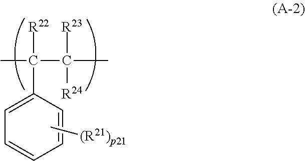

wherein
R²¹ is each independently C₁₋₅ alkyl (wherein methylene in the alkyl can be replaced with oxy); preferably methyl, ethyl, t-butyl or t-butoxy; more preferably methyl or ethyl; further preferably methyl.
R²², R²³ and R²⁴ are each independently hydrogen, C₁₋₅ alkyl, C₁₋₅ alkoxy or —COOH; preferably hydrogen or methyl; more preferably hydrogen.
p21 is 0 to 5; preferably 0, 1, 2, 3, 4 or 5; more preferably 0 or 1; further preferably 0.

An exemplified embodiment of the formula (A-2) includes the following:

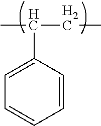

The formula (A-3) is as follows:

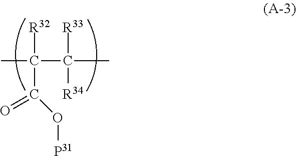

wherein
R³², R³³ and R³⁴ are each independently hydrogen, C₁₋₅ alkyl, C₁₋₅ alkoxy or —COOH; preferably hydrogen, methyl, ethyl, t-butyl, methoxy, t-butoxy or —COOH; more preferably hydrogen or methyl; further preferably hydrogen.
P³¹ is C₄₋₂₀ alkyl. A part or all of the alkyl can form a ring, a part or all of H in the alkyl can be replaced with halogen, and methylene in the alkyl can be replaced with oxy or carbonyl. The alkyl moiety of P³¹ is preferably branched or cyclic. When the C₄₋₂₀ alkyl in P³¹ is replaced with halogen, it is preferable that all are replaced, and the halogen that replaces is preferably F or Cl; more preferably F. It is a preferred embodiment of the present invention that H of the C₄₋₂₀ alkyl in P³¹ is not replaced with any halogen. P³¹ is preferably methyl, isopropyl, t-butyl, cyclopentyl, methylcyclopentyl, ethylcyclopentyl, cyclohexyl, methylcyclohexyl, ethylcyclohexyl, adamantyl, methyladamantyl or ethyladamantyl; more preferably t-butyl, ethylcyclopentyl, ethylcyclohexyl or ethyladamantyl; further preferably t-butyl, ethylcyclopentyl or ethyladamantyl; further more preferably t-butyl.

Exemplified embodiments of the formula (A-3) include the following:

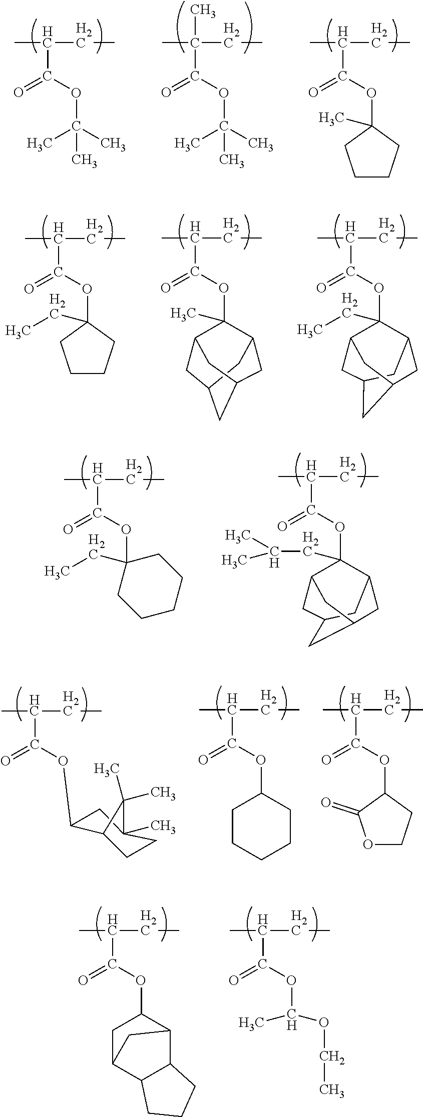

The formula (A-4) is as follows:

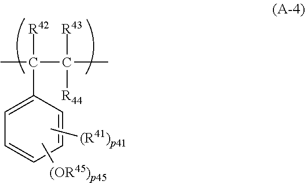

wherein
R⁴¹ is each independently C₁₋₅ alkyl (wherein methylene in the alkyl can be replaced with oxy); preferably methyl, ethyl or t-butyl; more preferably methyl.
R⁴⁵ is each independently C₁₋₅ alkyl (wherein methylene in the alkyl can be replaced with oxy); preferably methyl, t-butyl or —CH(CH₃)—O—CH₂CH₃.
R⁴², R⁴³ and R⁴⁴ are each independently hydrogen, C₁₋₅ alkyl, C₁₋₅ alkoxy or —COOH; preferably hydrogen or methyl; more preferably hydrogen.
p41 is 0 to 4; preferably 0 or 1; more preferably 0.
p45 is 1 to 2; preferably 1.
p41+p45≤5 is satisfied.

Exemplified embodiments of the formula (A-4) include the following:

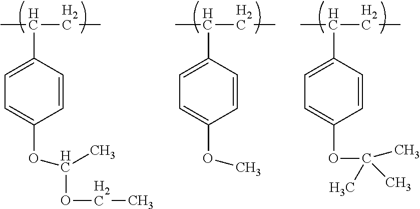

These structural units are appropriately blended according to the purpose. It is a preferred embodiment that the constituent is made so that the rate of increase in solubility in the alkaline aqueous solution by an acid becomes appropriate.
n_{A-1}, n_{A-2}, n_{A-3} and n_{A-4}, which are the numbers of repeating units represented by the formulae (A-1), (A-2), (A-3) and (A-4) in the polymer (A), are described below:
n_{A-1}/(n_{A-1}+n_{A-2}+n_{A-3}+n_{A-4}) is preferably 40 to 80%; more preferably 50 to 80%; further preferably 55 to 75%; further more preferably 55 to 65%.
n_{A-2}/(n_{A-1}+n_{A-2}+n_{A-3}+n_{A-4}) is preferably 0 to 40%; more preferably 0 to 30%; further preferably 5 to 25%; further more preferably 15 to 25%.
n_{A-3}/(n_{A-1}+n_{A-2}+n_{A-3}+n_{A-4}) is preferably 10 to 50%; more preferably 10 to 40%; further preferably 15 to 35%; further more preferably 15 to 25%.
n_{A-4}/(n_{A-1}+n_{A-2}+n_{A-3}+n_{A-4}) is preferably 0 to 40%; more preferably 0 to 30%; further preferably 0 to 10%; further more preferably 0 to 5%. It is also a preferred embodiment of the present invention that n_{A-4} is 0. A preferred embodiment includes the following:
n_{A-1}/(n_{A-1}+n_{A-2}+n_{A-3}+n_{A-4})=40 to 80%,
n_{A-2}/(n_{A-1}+n_{A-2}+n_{A-3}+n_{A-4})=0 to 40%,
n_{A-3}/(n_{A-1}+n_{A-2}+n_{A-3}+n_{A-4})=10 to 50%, and
n_{A-4}/(n_{A-1}+n_{A-2}+n_{A-3}+n_{A-4})=0 to 40%.

One embodiment of the present invention is that n_{A-3}>0 and n_{A-4}=0.

The polymer (A) can also contain a further repeating unit other than the repeating units represented by the formulae (A-1), (A-2), (A-3) and (A-4).

The further repeating unit is preferably a repeating unit comprising arylcarbonyl.

The content of the further repeating unit contained in the polymer (A) is preferably 0 to 10 mass parts; more preferably 0 to 5 mass parts; further preferably 0 to 1 mass parts, with respect to 100 mass parts of the polymer (A). It is also a preferred embodiment of the polymer (A) to contain no further repeating unit. In other words, it is also a preferred embodiment to contain no repeating unit comprising arylcarbonyl.

Exemplified embodiments of the polymer (A) include the following:

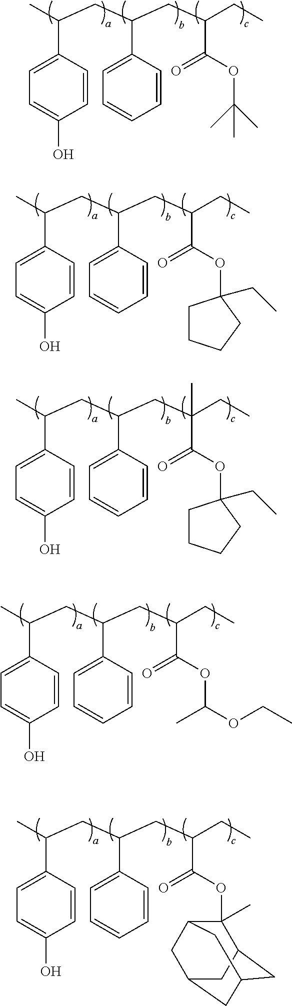

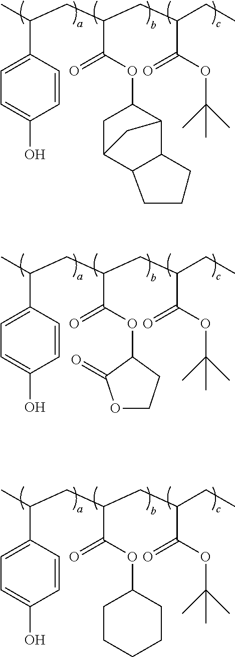

The mass average molecular weight (hereinafter referred to as Mw) of the polymer (A) is 5,000 to 19,000; more preferably 8,000 to 19,000; further preferably 10,000 to 19,000; further more preferably 11,000 to 13,000. Without wishing to be bound by theory, it can be thought that due to the polymer (A) having this Mw, it becomes possible to form a resist pattern with good rectangularity or resolution from the composition of the present invention.

In the present invention, Mw can be measured by gel permeation chromatography (GPC). In the measurement, it is a preferable example that a GPC column at 40 degrees Celsius, an elution solvent of tetrahydrofuran at 0.6 mL/min and monodisperse polystyrene as a standard are used.

The following is described for explanation. In the composition of the present invention, the polymer (A) can be used in any combination of any of two or more as long as they are represented by the above formula. For example, a composition containing the following two types of polymer (A) is also one embodiment of the present invention:

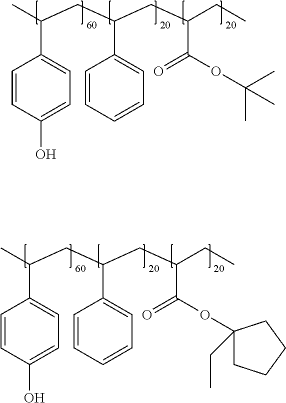

The same applies to the composition of the present invention in the following description unless otherwise specified.

The polymer (A) contained in the composition according to the present invention consists of one or two types of polymer; preferably, the polymer (A) consists of one type of polymer. Variations in Mw distribution and polymerization are allowed.

The content of the polymer (A) is preferably 10 to 40 mass %; more preferably 12 to 38 mass %; further preferably 15 to 36 mass %, based on the composition.

The composition according to the present invention can contain a polymer other than the polymer (A), but an embodiment in which no polymer other than the polymer (A) is one preferred embodiment.

### Photoacid Generator (B)

The composition according to the present invention comprises a photoacid generator (B). The photoacid generator (B) releases an acid upon irradiation with light. Preferably, the acid derived from the photoacid generator (B) acts on the polymer (A) to increase the solubility of the polymer (A) in an alkaline aqueous solution. For example, when the polymer (A) has an acid group protected by a protecting group, the protecting group is released by an acid. The photoacid generator (B) used in the composition according to the present invention can be selected from those conventionally known.

Upon exposure, the photoacid generator (B) releases an acid having an acid dissociation constant pKa (H₂O) of −20 to 1.4; more preferably −16 to 1.4; further preferably −16 to 1.2; further more preferably −16 to 1.1.

The photoacid generator (B) is preferably represented by the formula (B-1).

Bⁿ⁺cation Bⁿ⁻anion (B-1)
wherein
   the Bⁿ⁺cation is a cation represented by the formula (BC1), a cation represented by the formula (BC2) or a cation represented by the formula (BC3); preferably the cation represented by the formula (BC1) or the cation represented by the formula (BC2); more preferably the cation represented by the formula (BC1). The Bⁿ⁺cation is n valent as a whole, and n is 1 to 3. The Bⁿ⁻anion is a sulfonate anion, and preferably an anion represented by the formula (BA1), an anion represented by the formula (BA2), an anion represented by the formula (BA3) or an anion represented by the formula (BA4); more preferably an anion represented by the formula (BA3). The B⁻anion is n valent as a whole.

n is preferably 1 or 2; more preferably 1.

Without wishing to be bound by theory, it is thought to become possible, using the photoacid generator (B) as described above, to control a large amount of the photoacid generator (B) is present near the bottom of the resist film when it is formed and to control the shape of the pattern to be a rectangular shape. In a positive type resist, the exposed area is solubilized, but the amount of light decreases while reaching the bottom of the resist film; therefore, it is effective to control the pattern shape by the amount of the photoacid generator (B).

The formula (BC1) is as follows:

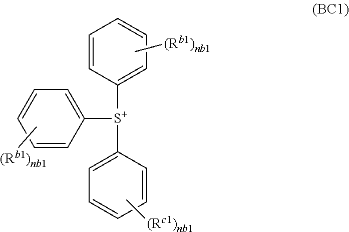

wherein
R^{b1} is each independently C₁₋₆ alkyl, C₁₋₆ alkoxy, C₆₋₁₂ aryl, C₆₋₁₂ arylthio or C₆₋₁₂ aryloxy; preferably methyl, ethyl, t-butyl, methoxy, ethoxy, phenylthio or phenyloxy; more preferably t-butyl, methoxy, ethoxy, phenylthio or phenyloxy.
nb1 is each independently 0, 1, 2 or 3; preferably 0 or 1; more preferably 0.

Exemplified embodiments of the formula (BC1) include the following:

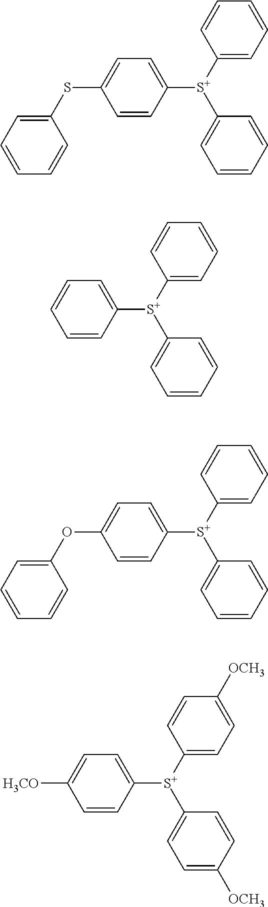 [SMILES: c1ccc(Sc2ccc([S+](c3ccccc3)c3ccccc3)cc2)cc1 ; c1ccc([S+](c2ccccc2)c2ccccc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1]

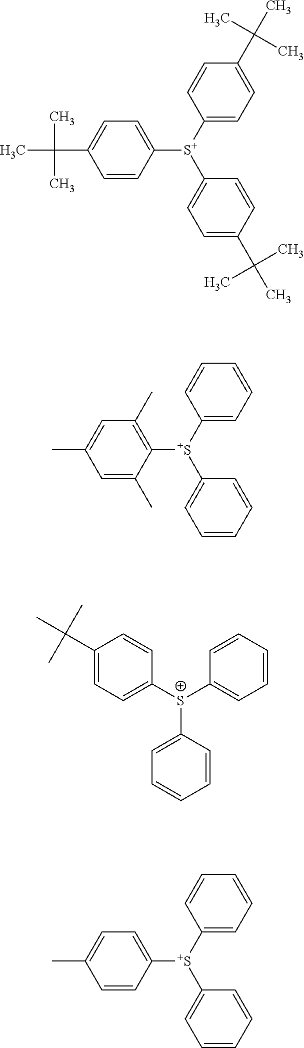

The formula (BC2) is as follows:

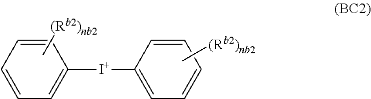

wherein
R^{b2} is each independently C₁₋₆ alkyl, C₁₋₆ alkoxy or C₆₋₁₂ aryl; preferably alkyl having a C₄₋₆ branched structure. R^{b2} in the formula can be identical to or different from each other, and one in which they are identical to each other is more preferable. R^{b2} is further preferably t-butyl or 1,1-dimethylpropyl; further more preferably t-butyl.
nb2 is each independently 0, 1, 2 or 3; preferably 1.

Exemplified embodiments of the formula (BC2) include the following:

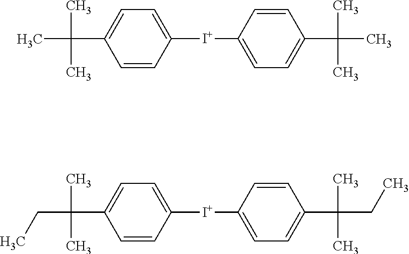

The formula (BC3) is as follows:

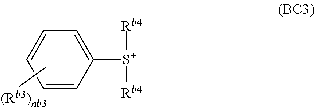

wherein
R^{b3} is each independently hydroxy, C₁₋₆ alkyl, C₁₋₆ alkoxy or C₆₋₁₂ aryl; preferably methyl, ethyl, methoxy or ethoxy; more preferably methyl or methoxy.
R^{b4} is each independently C₁₋₆ alkyl; preferably methyl, ethyl, propyl or butyl. Two R^{b4} can be bonded to each other to form a ring structure, and when a ring is formed, it is preferred to form a 5- or 6-membered alicycle.
nb3 is each independently 0, 1, 2 or 3; preferably 1, 2 or 3; more preferably 1 or 3.

Exemplified embodiments of the formula (BC3) include the following:

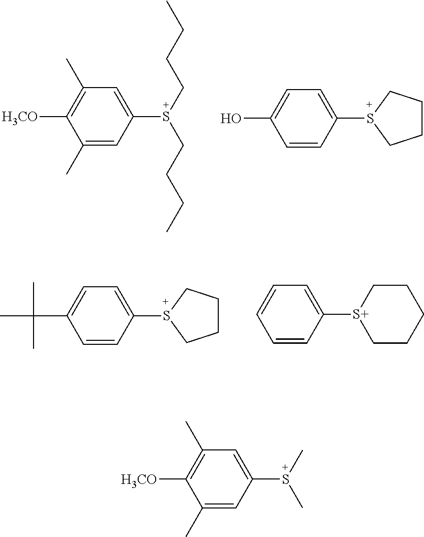

The formula (BA1) is as follows:

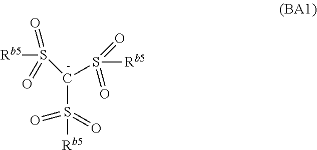

wherein
R^{b5} is each independently fluorine-substituted C₁₋₆ alkyl, fluorine-substituted C₁₋₆ alkoxy, or C₁₋₆ alkyl. For example, —CF₃ means that all of hydrogen in methyl (C₁) are replaced with fluorine. In the present invention, the fluorine substitution means that a part or all of hydrogen existing in the alkyl moiety are replaced with fluorine, and more preferably all of hydrogen are replaced with fluorine.

The alkyl moiety of R^{b}s is preferably methyl, ethyl or t-butyl; more preferably methyl.

R^{b5} is preferably fluorine-substituted alkyl; more preferably —CF₃.

An exemplified embodiment of the formula (BA1) includes the following:

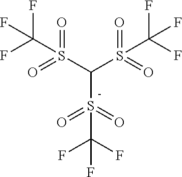 [SMILES: O=S(=O)(C(S(=O)(=O)C(F)(F)F)S(=O)(=O)C(F)(F)F)C(F)(F)F]

The formula (BA2) is as follows:

R^{b6}—SO₃⁻ (BA2)

wherein R^{b6} is fluorine-substituted C₁₋₁₀ alkyl, fluorine-substituted C₁₋₆ alkoxy, fluorine-substituted C₆₋₁₂ aryl, fluorine-substituted C₂₋₁₂ acyl, or fluorine-substituted C₆₋₁₂ alkoxyaryl; preferably fluorine-substituted C₁₋₁₀ alkyl. The alkyl moiety of R^{b6} is preferably linear or cyclic. R^{b6} is preferably fluorine-substituted C₁₋₆ alkyl; more preferably fluorine-substituted C₂₋₆ alkyl. Exemplified embodiments of the formula (BA2) include the following:

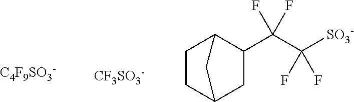

The formula (BA3) is as follows:

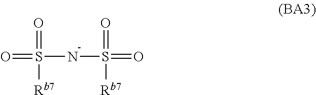

wherein
R^{b7} is each independently fluorine-substituted C₁₋₆ alkyl, fluorine-substituted C₁₋₆ alkoxy, fluorine-substituted C₆₋₁₂ aryl, fluorine-substituted C₂₋₁₂ acyl, or fluorine-substituted C₆₋₁₂ alkoxyaryl; preferably fluorine-substituted C₂₋₆ alkyl. Two R^{b7} can be bonded to each other to form a fluorine-substituted heterocyclic structure. The heterocyclic structure is preferably a saturated ring. The heterocyclic structure, including N and S, is preferably a 5- to 8-membered monocyclic structure; more preferably a 5- or 6-membered ring; further preferably a 6-membered ring.

Exemplified embodiments of the formula (BA3) include the following:

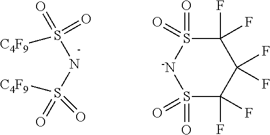

The formula (BA4) is as follows:

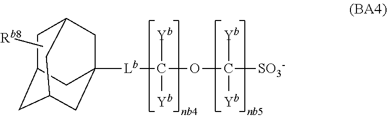

wherein
R^{b8} is hydrogen, C₁₋₆ alkyl, C₁₋₆ alkoxy or hydroxy; preferably hydrogen, methyl, ethyl, methoxy or hydroxy; more preferably hydrogen or hydroxy.
L^{b} is methylene, ethylene, carbonyl, oxy or carbonyloxy; preferably ethylene or carbonyl.
Y^{b} is each independently hydrogen or fluorine; preferably, one or more of Y^{b} is fluorine.
nb4 is an integer of 0 to 10; preferably 0, 1 or 2.
nb5 is an integer of 0 to 21; preferably 4, 5 or 6.

Exemplified embodiments of the formula (BA4) include the following:

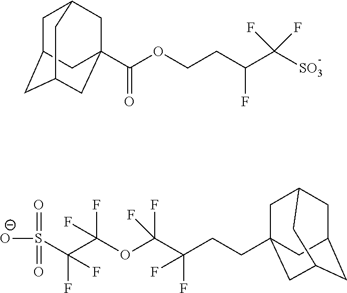

The molecular weight of the photoacid generator (B) is preferably 300 to 1,200; more preferably 400 to 900.

The content of the photoacid generator (B) is preferably 0.3 to 4 mass parts; more preferably 0.4 to 2 mass parts; further preferably 0.5 to 2 mass parts, with respect to 100 mass parts of the polymer (A). Without wishing to be bound by theory, it is thought that because the content of the photoacid generator (B) is within the above range, a resist pattern with better resolution can be formed.

The composition according to the present invention can contain a photoacid generator other than the photoacid generator (B), and examples thereof include a photoacid generator (B′) represented by the following formula (B′-1). In the present invention, the photoacid generator (B′) is different from the photoacid generator (B). As a preferred embodiment of the present invention, the acid that directly acts on the polymer (A) is an acid released not from the photoacid generator (B′) but from the photoacid generator (B).

As a preferred embodiment of the present invention, the cation derived from the photoacid generator (B′) reacts with the anion portion derived from the photoacid generator (B) and functions as a quencher. The photoacid generator (B′) functions as a quencher that suppresses the diffusion of the acid derived from the photoacid generator (B), which generated in the exposed area.
photoacid generator (B′) is represented by the formula (B′-1):

B′^{m+}cation B′^{m-}anion (B-1)
wherein
the B′^{m+}cation is a cation represented by the above-described formula (BC1) or the cation represented by the formula (BC2). Preferred embodiments are also the same as described above.

The B′^{m+}cation is m valent as a whole, and m is 1 to 3.

The B′^{m-}anion is an anion represented by the formula (B′A1) or an anion represented by the formula (B′A2). The B′^{m-}anion is m valent as a whole.

m is preferably 1 or 2; more preferably 1.

The formula (B′A1) is as follows:

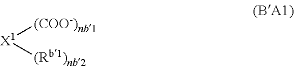

wherein
X¹ is a C₁₋₂₀ hydrocarbon or a single bond,
R^{b′1} is each independently hydrogen, hydroxy, C₁₋₆ alkyl or C₆₋₁₀ aryl,
nb′1 is 1, 2 or 3, and
nb′2 is 0, 1 or 2.

When X¹ is a hydrocarbon, it can be any one of linear, branched or cyclic, preferably linear or cyclic. In the case of linear, it is preferably C₁₄ (more preferably C₁₋₂), and preferably has one double bond in the chain or is a saturated one. When it is cyclic, it can be a monocyclic aromatic one, or a saturated monocyclic or polycyclic one. In the case of monocyclic, a 6-membered ring is preferred, and in the case of polycyclic, adamantane ring is preferred.

X¹ is preferably methyl, ethyl, propyl, butyl, ethane, phenyl, cyclohexane, adamantane or a single bond; more preferably methyl, phenyl, cyclohexane or a single bond; further preferably phenyl or a single bond; further more preferably phenyl.

nb′1 is preferably 1 or 2; more preferably 1.

nb′2 is preferably 0 or 1; more preferably 1.

R^{b′1} is preferably hydroxy, methyl, ethyl, 1-propyl, 2-propyl, t-butyl or phenyl; more preferably hydroxy.

When X¹ is a single bond, R^{b′1} is preferably hydrogen. When in (B′A1), X¹ is a single bond, R^{b′1} is hydrogen and nb′1=nb′2=1, an anion that is H—COO⁻ is represented.

Exemplified embodiments of the formula (B′A1) include the following:

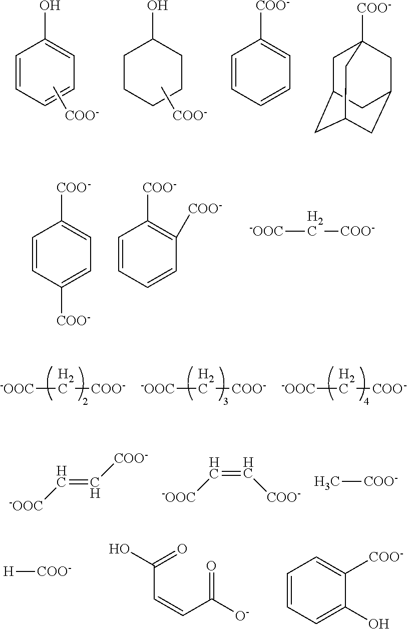

The formula (B′A2) is as follows:

R^{b′2}—SO₃⁻ (B′A2)
wherein
R^{b′2} is C₁₋₂₀ alkyl (wherein a part or all of the alkyl can form a ring, and —CH₂— in the alkyl can be replaced with —C(═O)—). R^{b′2} is preferably C₃₋₁₃ alkyl; more preferably C₅₋₁₂ alkyl; further preferably C₅₋₁₂ alkyl; further more preferably C₁₀ alkyl. The alkyl of R^{b′2} preferably a part or all thereof forms a ring; more preferably a part thereof forms a ring. Preferably, one or more (more preferably one) —CH₂— in the alkyl of R^{b′2} is replaced with —C(═O)—.

Exemplified embodiments of the formula (B′A2) include the following:

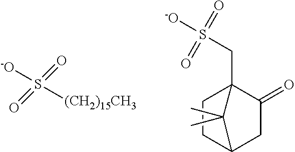

Upon exposure, the photoacid generator (B′) releases an acid with an acid dissociation constant pKa(H₂O) of preferably 1.5 to 8; more preferably 1.5 to 5.

The molecular weight of the photoacid generator (B′) is preferably 300 to 1,400; more preferably 300 to 1,200.

The content of the photoacid generator (B′) is preferably 0.01 to 5 mass %; more preferably 0.03 to 1 mass %; further preferably 0.05 to 1 mass %; further more preferably 0.5 to 1 mass %, based on the polymer (A). It is also a preferred embodiment of the present invention that no photoacid generator (B′) is contained.

### Solvent (C)

The composition according to the present invention comprises a solvent (C). The solvent is not particularly limited as long as it can dissolve each component to be mixed.

Exemplified embodiments of the solvent include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonanone, cyclohexanone, cyclopentanone, methylcyclohexanone, 2,4-pentanedione, acetonylacetone, diacetone alcohol, acetophenone, fenthion, ethyl ether, i-propyl ether, n-butyl ether (di-n-butyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone, γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), γ-butyrolactone, n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of any two or more of these.

The solvent (C) is preferably propylene glycol monomethyl ether, propylene glycol monomethyl ether acetate, ethyl lactate, n-butyl acetate, n-butyl ether, 2-heptanone, cyclohexanone, or any combination of any of these; more preferably PGME, EL, nBA, DBE, or any mixture of any of these; further preferably PGME, EL, or any mixture of any of these; further more preferably a mixture of PGME and EL. When two types are mixed, the mass ratio of the first solvent to the second solvent is preferably 95:5 to 5:95 (more preferably 90:10 to 10:90; further preferably 80:20 to 20:80).

In relation to other layers or films, it is also one embodiment that the solvent (C) substantially contains no water. For example, the amount of water in the whole solvent (C) is preferably 0.1 mass % or less; more preferably 0.01 mass % or less; further preferably 0.001 mass % or less. It is also a preferable embodiment that the solvent (C) contains no water (0 mass %).

The content of the solvent (C) is preferably 50 to 90 mass %; more preferably 60 to 88 mass %; further preferably 65 to 85 mass %, based on the composition. By increasing or decreasing the amount of the solvent occupying in the whole composition, the film thickness after film formation can be controlled.

### Basic Compound (D)

The composition according to the present invention can further contain a basic compound (D). The basic compound has the effect of suppressing the diffusion of the acid generated in the exposed area and the effect of suppressing the deactivation of the acid on the surface of the resist film by the amine component contained in the air.

The basic compound (D) is preferably ammonia, C₁₋₁₆ primary aliphatic amine, C₂₋₃₂ secondary aliphatic amine, C₃₋₄₈ tertiary aliphatic amine, C₆₋₃₀ aromatic amine, C₅₋₃₀ heterocyclic amine, or any combination of any of these.

Exemplified embodiments of the basic compound (D) include ammonia, ethylamine, n-octylamine, n-heptylamine, ethylenediamine, triethylamine, tri-n-octylamine, diethylamine, tris[2-(2-methoxyethoxy)ethyl]amine, 1,8-diazabicyclo[5.4.0]undecene-7,1,5-diazabicyclo[4.3.0]nonene-5,7-methyl-1,5,7-triazabicyclo[4.4.0]dec-5-ene, 1,5,7-triazabicyclo[4.4.0]dec-5-ene.

The base dissociation constant pKb(H₂O) of the basic compound (D) is preferably −12 to 5; more preferably 1 to 4.

The molecular weight of the basic compound (D) is preferably 17 to 500; more preferably 60 to 400.

The content of the basic compound (D) is preferably 0.01 to 5 mass parts; more preferably 0.05 to 2 mass parts, with respect to 100 mass parts of the polymer (A).

### Surfactant (E)

The composition according to the present invention can further contain a surfactant (E). The coatability can be improved by making a surfactant be comprised in it. Examples of the surfactant that can be used in the present invention include (I) anionic surfactants, (II) cationic surfactants or (III) nonionic surfactants, and more particularly (I) alkyl sulfonate, alkyl benzene sulfonic acid and alkyl benzene sulfonate, (II) lauryl pyridinium chloride and lauryl methyl ammonium chloride and (III) polyoxyethylene octyl ether, polyoxyethylene lauryl ether, polyoxyethylene acetylenic glycol ether, fluorine-containing surfactants (for example, Fluorad (3M), Megaface (DIC) and Surflon (AGC)), and organic siloxane surfactants (for example, KF-53 and KP341 (Shin-Etsu Chemical)).

These surfactants can be used alone or in combination of any two or more of these. The content of the surfactant (E) is preferably 0.005 to 1 mass parts; more preferably 0.01 to 0.2 mass parts, with respect to 100 mass parts of the polymer (A).

### Dye (F)

The composition according to the present invention can further contain a dye (F). By including the dye (F), the pattern shape can be improved.

The content of the dye (F) is preferably 0 to 0.5 mass parts; more preferably 0 to 0.2 mass parts; further preferably 0 to 0.1 mass parts, with respect to 100 mass parts of the polymer (A). Since the resist film of the present invention preferably has a high transmittance, it is preferred that the resist film does not substantially contain any dye. It is also a more preferred embodiment of the present invention that the composition according to the present invention contains no dye (F) (0 mass parts).

### Additive (G)

The composition according to the present invention can further contain an additive (G) other than the above components. The additive (G) is preferably a surface smoothing agent, a plasticizer, a contrast enhancer, an acid, a radical generator, a substrate adhesion enhancer, an antifoaming agent, or any combination of any of these.

The content of the additive (G) (in the case of a plurality of additives, the sum thereof) is preferably 0 to 5 mass parts; more preferably 0 to 3 mass parts; further preferably 0 to 1 mass parts, with respect to 100 mass parts of the polymer (A). It is also one embodiment of the present invention that the composition according to the present invention contains no additive (G) (0 mass parts).

The acid can be used to adjust the pH value of the composition and improve the solubility of the additive components. The acid used is not particularly limited, but examples thereof include formic acid, acetic acid, propionic acid, benzoic acid, phthalic acid, salicylic acid, lactic acid, malic acid, citric acid, oxalic acid, malonic acid, succinic acid, fumaric acid, maleic acid, aconitic acid, glutaric acid, adipic acid, and any combination of any of these.

In the present invention, the content of salicylic acid is preferably 0 to 0.005 mass parts; more preferably 0 to 0.001 mass parts, with respect to 100 mass parts of the polymer (A). It is also one embodiment of the invention that the composition according to the invention contains no salicylic acid (0 mass parts).

### Method for Manufacturing a Processed Substrate

The method for manufacturing a processed substrate according to the present invention comprises the following steps:
manufacturing a resist pattern using the composition according to the present invention; and performing an ion implantation using the resist pattern as a mask, or
processing the underlayer of the resist pattern using the resist pattern as a mask to form a underlayer pattern, and performing an ion implantation using the underlayer pattern as a mask.

Hereinafter, one embodiment of the manufacturing method according to the present invention is described.

The composition according to the present invention is applied above a substrate (for example, a silicon/silicon dioxide coated substrate, a silicon nitride substrate, a silicon wafer substrate, a glass substrate, an ITO substrate, and the like) by an appropriate method. In the present invention, the “above” includes a case where a layer or film is formed immediately on a substrate and a case where a layer or film is formed above a substrate via another layer. For example, a planarization film or resist underlayer film can be formed immediately on a substrate, and the composition according to the present invention can be applied immediately on the film. The resist underlayer film includes a BARC layer. The application method is not particularly limited, and examples thereof include a coating method using a spinner or a coater. After application, a film according to the present invention is formed by heating. This heating is performed, for example, by a hot plate. The heating temperature is preferably 100 to 250° C.; more preferably 100 to 200° C.; further preferably 100 to 160° C. The temperature is a temperature of heating atmosphere, for example, that of a heating surface of a hot plate. The heating time is preferably 30 to 300 seconds; more preferably 30 to 120 seconds; further preferably 45 to 90 seconds. The heating is preferably performed in an air or a nitrogen gas atmosphere.

The resist film formed by the present invention has high transmittance. The transmittance at a wavelength of 248 nm is preferably 15 to 50%; more preferably 17 to 40%, when the film thickness of the resist film is 5 μm. With these transmittances, the exposure light also reaches the lower portion of the film when the film is thick, and a resist pattern with high rectangularity can be formed.

The resist film is exposed through a predetermined mask. Although the wavelength of light used for exposure is not particularly limited, it is preferable to perform exposure with light having a wavelength of 13.5 to 248 nm. KrF excimer laser (wavelength: 248 nm), ArF excimer laser (wavelength: 193 nm), extreme ultraviolet (wavelength: 13.5 nm) and the like can be used, and KrF excimer laser is preferred. These wavelengths allow a range of ±1%. After exposure, post exposure bake (PEB) can be performed as required. The PEB temperature is preferably 80 to 160° C.; more preferably 100 to 150° C., and the heating time is 0.3 to 5 minutes; preferably 0.5 to 2 minutes.

The exposed resist film is developed using a developer. As the developing method, any method conventionally used for developing a photoresist, such as a paddle developing method, an immersion developing method, or a swinging immersion developing method, can be used. As the developer, aqueous solution containing an inorganic alkali, such as sodium hydroxide, potassium hydroxide, sodium carbonate and sodium silicate; an organic amine, such as ammonia, ethylamine, propylamine, diethylamine, diethylaminoethanol and triethylamine; a quaternary amine, such as tetramethylammonium hydroxide (TMAH); and the like are used, and a 2.38 mass % TMAH aqueous solution is preferred. A surfactant can also be further added to the developer. The temperature of the developer is preferably 5 to 50° C.; more preferably 25 to 40° C., and the development time is preferably 10 to 300 seconds; more preferably 30 to 60 seconds. After development, washing with water or rinsing can also be performed as necessary. When a positive type resist composition is used, the exposed area is removed by development to form a resist pattern. The resist pattern can also be further made finer, for example, using a shrink material.

When the composition according to the present invention is used, it is possible to form a resist pattern with high resolution, that is, a resist pattern with a high aspect ratio, while it is a thick resist. When the film thickness of the resist film is 3 μm, the resolution is preferably 150 to 220 nm; more preferably 160 to 200 nm.

When the composition according to the present invention is used, it is possible to form a resist pattern with high rectangularity. When the composition according to the present invention is a positive type resist pattern forming composition, assuming that Wt is the width of the top portion of the resist pattern and Wb is the width of the bottom portion of the resist pattern, Wt/Wb (hereinafter referred to as Pr) is preferably 0.6 to 1.7; more preferably 0.7 to 1.0; further preferably 0.8 to 1.0.

It is preferable to measure by adjusting the conditions for comparing these numerical values as closely as possible to those in Examples described later. For example, it is preferable to compare by forming a film with a film thickness of 3.0 μm, and forming a trench pattern with a line width of 0.8 am and a space width of 0.2 μm.

The formed resist pattern has high heat resistance. When the formed trench pattern with a film thickness of 3 μm, a line width of 0.8 am and a space width of 0.2 am is heated at 50° C. for 60 seconds, the line width variation at the top portion of the pattern before and after heating is preferably 50 nm or less; more preferably 35 nm or less.

A processed substrate is formed by performing an ion implantation using the resist pattern as a mask, or processing the underlayer of the resist pattern using the resist pattern as a mask to form a underlayer pattern and performing an ion implantation using the underlayer pattern as a mask.

The ion implantation can be performed by a known method using a known ion implantation apparatus. In the manufacture of semiconductor devices, liquid crystal display devices and the like, forming an impurity diffusion layer on a substrate surface is conducted. The formation of an impurity diffusion layer is usually performed in two stages of impurity introduction and diffusion thereof. As one method of the introduction, there is an ion implantation in which impurities such as phosphorus and boron are ionized in a vacuum, accelerated in a high electric field and implanted into the support surface. As the ion acceleration energy during ion implantation, an energy load of 10 to 200 keV is generally applied to the resist pattern, which can destroy the resist pattern.

Since the resist pattern formed according to the present invention is a thick film, has high rectangularity, and has high heat resistance, it can be suitably used for ion implantation applications in which ions are implanted at high energy.

Ion sources (impurity elements) include ions such as boron, phosphorus, arsenic and argon. Thin films on substrates include silicon, silicon dioxide, silicon nitride, aluminum and the like.

Thereafter, if necessary, further processing such as forming wiring on the processed substrate is performed to form a device. For these further processing, known methods can be applied. Examples of the device include a semiconductor device, a liquid crystal display device, an organic EL display device, a plasma display device, and a solar cell device. The device is preferably a semiconductor device.

### Examples

The present invention is described below with reference to various examples. The embodiment of the present invention is not limited only to these examples.

### Preparation of Composition 1

100 mass parts of polymer 1, 1.00 mass part of photoacid generator 1, 0.15 mass parts of basic compound 1, and 0.06 mass parts of surfactant 1 are added to a mixed solvent having a mass ratio of PGME:EL=70:30, so that the solid content ratio becomes 25.0 mass %. The resultant is stirred for 30 minutes at room temperature. It is visually checked that the added materials are dissolved. The resultant is filtered through a 0.05 μm filter. Thereby, Composition 1 is obtained.

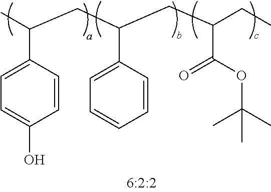

(Polymer 1) Hydroxystyrene:styrene:t-butyl acrylate copolymer, molar ratio 6:2:2, Mw:about 9,000
The above ratio indicates the ratio of the number of structural units of each repeating unit, and the same applies hereinafter.

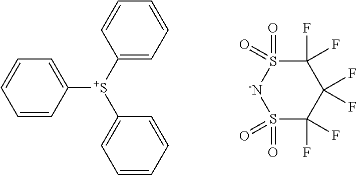

### (Photoacid Generator 1)

Basic compound 1:tris[2-(2-methoxyethoxy)-ethyl]amine
Surfactant 1:Megaface R-40, DIC Corporation

### Preparation of Compositions 2 to 11 and Comparative Composition 1

The constituent is changed as shown in Table 1, the solvent is the same as Composition 1, and the solid content ratio is the same as Composition 1, and the preparation is performed in the same manner as Composition 1 to obtain Compositions 2 to 11 and Comparative Composition 1. In the table, the numerical values of each constituent indicate mass parts.

TABLE 1
Table 1

| | | | | | | | | | | | | Comparative |
|---|---|---|---|---|---|---|---|---|---|---|---|---|
| | Composition | | | | | | | | | | | composition |
| | 1 | 2 | 3 | 4 | 5 | 6 | 7 | 8 | 9 | 10 | 11 | 1 |
| Polymer 1 | 100 | — | — | — | — | — | — | — | — | — | — | — |
| Polymer 2 | — | 100 | — | — | 100 | 100 | — | — | — | 100 | 99.5 | — |
| Polymer 3 | — | — | 100 | — | — | — | — | — | — | — | — | — |
| Polymer 4 | — | — | — | 100 | — | — | — | — | — | — | — | — |
| Polymer 5 | — | — | — | — | — | — | — | — | — | — | — | 100 |
| Polymer 6 | — | — | — | — | — | — | 100 | — | — | — | — | — |
| Polymer 7 | — | — | — | — | — | — | — | 100 | — | — | — | — |
| Polymer 8 | — | — | — | — | — | — | — | — | 100 | — | — | — |
| Polymer 9 | — | — | — | — | — | — | — | — | — | — | 0.5 | — |
| Photoacid | 1 | 1 | 1 | 1 | 0.5 | 2 | 1 | 1 | 1 | — | 1 | 1 |
| generator 1 | | | | | | | | | | | | |
| Photoacid | — | — | — | — | — | — | — | — | — | 1 | — | — |
| generator 2 | | | | | | | | | | | | |
| Basic | 0.15 | 0.15 | 0.15 | 0.15 | 0.15 | 0.15 | 0.15 | 0.15 | 0.15 | 0.15 | 0.15 | 0.15 |
| compound1 | | | | | | | | | | | | |
| Surfactant 1 | 0.06 | 0.06 | 0.06 | 0.06 | 0.06 | 0.06 | 0.06 | 0.06 | 0.06 | 0.06 | 0.06 | 0.06 |

In the table,
Polymer 2

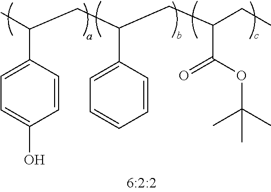

Hydroxystyrene:styrene:t-butyl acrylate copolymer, molar ratio 6:2:2, Mw:about 12,000
Polymer 3

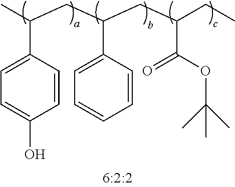

Hydroxystyrene:styrene:t-butyl acrylate copolymer, molar ratio 6:2:2, Mw:about 15,000
Polymer 4

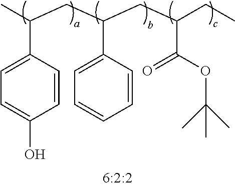

Hydroxystyrene:styrene:t-butyl acrylate copolymer, molar ratio 6:2:2, Mw:about 18,000
Polymer 5 (comparative polymer)

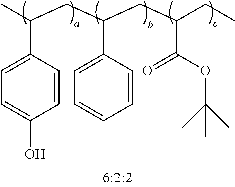

Hydroxystyrene:styrene:t-butyl acrylate copolymer, molar ratio 6:2:2, Mw:about 24,000
Polymer 6

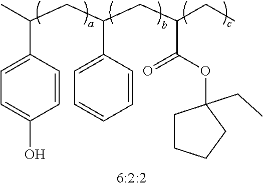

Hydroxystyrene:styrene:ethylcyclopentyl acrylate copolymer, molar ratio 6:2:2, Mw:about 12,000
Polymer 7

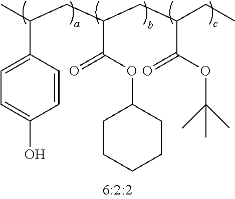

Hydroxystyrene:cyclohexyl acrylate:t-butyl acrylate copolymer, molar ratio 6:2:2, Mw:about 12,000
Polymer 8

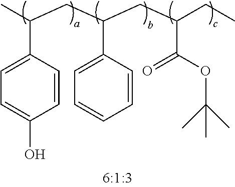

Hydroxystyrene:styrene:t-butyl acrylate copolymer, molar ratio 6:1:3, Mw:about 12,000
Polymer 9

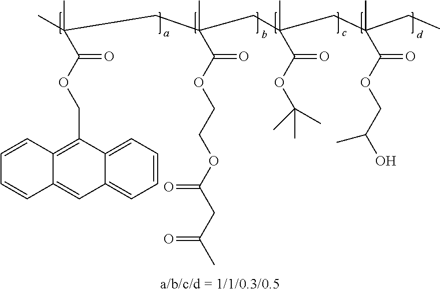

Anthracenemethanol methacrylate:acetoacetoxyethyl methacrylate:2-hydroxypropyl methacrylate:t-butyl methacrylate copolymer, molar ratio 1:1:0.3:0.5, Mw:about 15,000
Photoacid generator 2

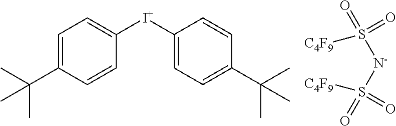

### Example of Resist Pattern Formation

Using a coater developer Mark 8 (Tokyo Electron), the composition prepared above is dropped onto an 8 inch Si wafer and spin-coating is performed. This wafer is heated at 140° C. for 90 seconds using a hot plate under atmospheric conditions to form a resist film. The thickness of the resist film at this point is 3.0 μm when measured by an optical interference type film thickness measuring device M-1210 (SCREEN).

This resist film is exposed using a KrF stepper FPA3000-EX5 (Canon). The exposed wafer is heated (PEB) at 120° C. for 90 seconds using a hot plate under atmospheric conditions. Thereafter, this resist film is puddle-developed with a 2.38 mass % TMAH aqueous solution for 60 seconds, washed with DIW, and spin-dried at 1,000 rpm. Thereby, a trench pattern with a line width of 0.8 μm and a space width of 0.2 μm is formed. The line width and space width are values measured at the bottom portion of the pattern.

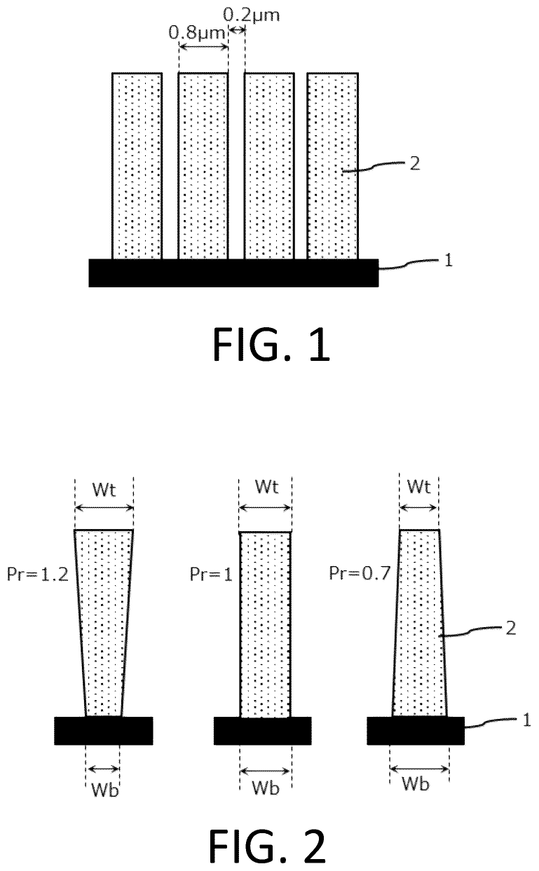

FIG. 1 schematically shows a vertical cross-sectional shape of this pattern. A trench pattern 2 is formed on a substrate 1. The exposure dose for forming a trench pattern having a line width of 0.8 am and a space width of 0.2 am is taken as the optimum exposure dose, and the resolution described later is evaluated at this optimum exposure dose.

### Evaluation of Pattern Rectangularity

A section of the sample formed in the above-described “Example of resist pattern formation” is formed and the vertical cross section of the pattern is observed with a scanning type electron microscope (SEM). The ratio of the width of the top portion of the pattern to the width of the bottom portion of the pattern is evaluated. FIG. 2 schematically shows a vertical cross section, in which a trench pattern 2 is formed on a substrate 1. It is assumed that Wt is the width of the top portion of the pattern, and Wb is the width of the bottom portion of the pattern. This ratio Pr is defined as Pr=Wt/Wb and used as an index for the rectangularity evaluation of the pattern.

The evaluation criteria are as follows:
A: Pr is 0.8 to 1.0.
B: Pr is 0.7 to 0.8.
C: Pr is 1.0 or more, or 0.7 or less.

The evaluation results are described in Table 2.

### Evaluation of Resolution

Using a mask pattern with a space size of 0.25 to 0.16 μm, exposure is performed with the optimum exposure doze by the pattern forming method described above. The resolution is taken as the minimum dimension (μm) of the resist pattern that is resolved when exposed with the optimum exposure dose. For those that cannot form a pattern of 0.20 μm, the minimum size that can be formed is taken as the resolution.

The evaluation results are described in Table 2.

### Evaluation of Transmittance

Each composition is dropped onto a quartz substrate and spin-coating is performed. This wafer is heated at 140° C. for 90 seconds using a hot plate under atmospheric conditions to form a resist film having a film thickness of 5.0 μm. The transmission spectrum of this film is measured using an ultraviolet-visible spectrometer (Thermo Fisher Scientific). The transmittance at 248 nm at this time is taken as the transmittance for evaluation. The reference is a quartz substrate on which no resist film is formed.

### Evaluation of Heat Resistance

The substrate patterned in the above-described “Example of resist pattern formation” is heated at 150° C. for 60 seconds using a hot plate. After that, a change in pattern shape is observed using an SEM from a vertical cross section. The evaluation criteria are as follows:
A: No change in shape is observed
B: There is a change at the top portion of the resist pattern, and the amount of deformation is 50 nm or less.
C: The amount of deformation at the top portion of the resist pattern is larger than 50 nm.

TABLE 2
Table 2

| | | | | | | Heat | | Evaluation |
|---|---|---|---|---|---|---|---|---|
| | | Evaluation | | Evaluation | | resistance | | of |
| | | of | | of | Transmittance | deformation | | heat |
| | Pr | rectangularity | Resolution | resolution | % T | amount | | resistance |
| Composition 1 | 0.77 | B | 185 nm | A | 23 | 20 | nm | B |
| Composition 2 | 0.82 | A | 190 nm | A | 23 | 0 | nm | A |
| Composition 3 | 0.84 | A | 195 nm | B | 23 | 0 | nm | A |
| Composition 4 | 0.82 | A | 200 nm | B | 23.5 | 0 | nm | A |
| Composition 5 | 0.95 | A | 200 nm | B | 27 | 0 | nm | A |
| Composition 6 | 0.71 | B | 180 nm | A | 19 | 0 | nm | A |
| Composition 7 | 0.89 | A | 180 nm | A | 23 | 0 | nm | A |
| Composition 8 | 0.86 | A | 200 nm | B | 26 | 30 | nm | B |
| Composition 9 | 0.77 | B | 200 nm | B | 23 | 10 | nm | A |
| Composition 10 | 0.85 | A | 170 nm | A | 23 | 0 | nm | A |
| Comparative | 0.51 | C | 205 nm | C | 24 | 0 | nm | A |

composition 1

### Evaluation of Composition 11

The following evaluations are performed using Composition 11.

When the resolution is evaluated in the same manner as above, the resolution is 180 nm, which is rated an A. When the heat resistance is evaluated in the same manner as above, the amount of deformation is 0 nm, which is rated an A.

### EXPLANATION OF SYMBOLS

1. substrate
2. trench patterns

1. An ion implantation thick film resist composition comprising a polymer (A), a photoacid generator (B) and a solvent (C),
wherein,
the film thickness of the resist film formed from the composition is 1.0 to 50 μm;
the mass average molecular weight of the polymer (A) is 5,000 to 19,000; and
the polymer (A) comprises at least one of the repeating unit represented by formulae (A-1), (A-2), (A-3) and (A-4): 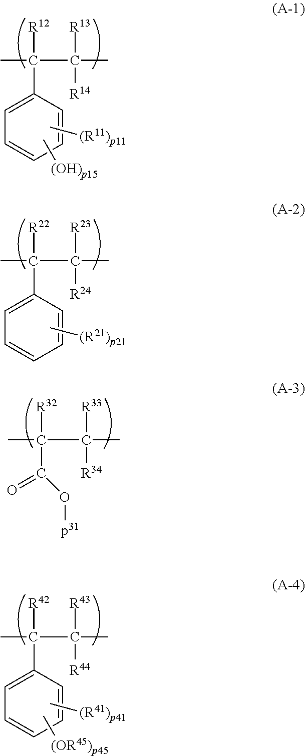
R¹¹, R²¹, R⁴¹ and R⁴⁵ are each independently C₁₋₅ alkyl (wherein methylene in the alkyl can be replaced with oxy);
R¹², R¹³, R¹⁴, R²², R²³, R²⁴, R³², R³³, R³⁴, R⁴², R⁴³ and R⁴⁴ are each independently hydrogen, C₁₋₅ alkyl, C₁₋₅ alkoxy or —COOH;
p11 is 0 to 4, p15 is 1 to 2, and p11+p15≤5;
p21 is 0 to 5;
p41 is 0 to 4, p45 is 1 to 2, and p41+p45≤5;
P31 is C₄₋₂₀ alkyl, wherein a part or all of the alkyl may optionally form a ring, a part or all of H in the alkyl may be replaced with halogen, and methylene in the alkyl may be replaced with oxy or carbonyl.

2. The composition according to claim 1, wherein the composition imparts to the resist film a transmittance at a wavelength of 248 nm is 15 to 50% when the film thickness of the resist film is 5 μm.

3. The composition according to claim 1, wherein n_{A-1}, n_{A-2}, n_{A-3} and n_{A-4}, which are the numbers of repeating units represented by formulae (A-1), (A-2), (A-3) and (A-4) in the polymer (A) satisfy at least one of the following ratios:
n_{A-1}/(n_{A-1}+n_{A-2}+n_{A-3}+n_{A-4})=40 to 80%,
n_{A-2}/(n_{A-1}+n_{A-2}+n_{A-3}+n_{A-4})=0 to 40%,
n_{A-3}/(n_{A-1}+n_{A-2}+n_{A-3}+n_{A-4})=10 to 50%, and
n_{A-4}/(n_{A-1}+n_{A-2}+n_{A-3}+n_{A-4})=0 to 40%.

4. The composition according to claim 3, wherein nₜₒₜₐₗ, which is the number of all repeating units contained in the polymer (A), satisfies the following:
(n_{A-1}+n_{A-2}+n_{A-3}+n_{A-4})/nₜₒₜₐₗ=80 to 100%.

5. The composition according to one or more of claims 1 to 3, wherein the composition imparts to the resist film a resolution of 150 to 220 nm when the film thickness of the resist film is 3 μm.

6. The composition according to claim 1, wherein the composition imparts to a trench pattern having a film thickness of 3 μm, a line width of 0.8 am and a space width of 0.2 μm formed from the resist film, which when the trench pattern is heated at 50° C. for 60 seconds, the line width variation at the top portion of the pattern before and after heating is 50 nm or less, and
in the trench pattern, the width Wt of the top portion of the pattern and the width Wb of the bottom portion of the pattern satisfy the following:
0.6≤Wt/Wb≤1.7

7. The composition according to claim 1, wherein the photoacid generator (B) is represented by the formula (B-1):
Bⁿ⁺cation Bⁿ⁻anion (B-1)
wherein
the Bⁿ⁺cation is a cation represented by the formula (BC1), a cation represented by the formula (BC2) or a cation represented by the formula (BC3), the Bⁿ⁺cation is n valent as a whole, and n is 1 to 3, and
the Bⁿ⁻anion is an anion represented by the formula (BA1), an anion represented by the formula (BA2), an anion represented by the formula (BA3) or an anion represented by the formula (BA4), and the Bⁿ⁻anion is n valent as a whole: 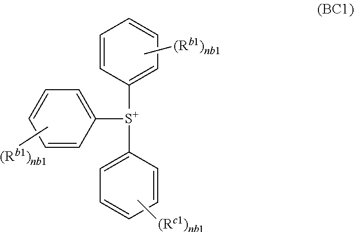
wherein
R^{b1} is each independently C₁₋₆ alkyl, C₁₋₆ alkoxy, C₆₋₁₂ aryl, C₆₋₁₂ arylthio or C₆₋₁₂ aryloxy, and
nb1 is each independently 0, 1, 2 or 3; 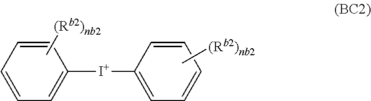
wherein
R^{b2} is each independently C₁₋₆ alkyl, C₁₋₆ alkoxy or C₆₋₁₂ aryl, and
nb2 is each independently 0, 1, 2 or 3; 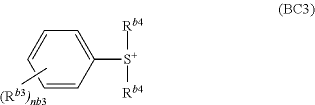
wherein
R^{b3} is each independently hydroxy, C₁₋₆ alkyl, C₁₋₆ alkoxy or C₆₋₁₂ aryl,
R^{b4} is each independently C₁₋₆ alkyl, provided that two R^{b4} can be bonded to each other to form a ring structure, and
nb3 is each independently 0, 1, 2 or 3; 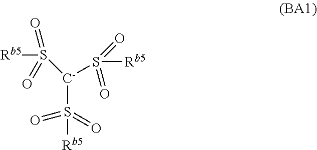
wherein
R^{b}s is each independently fluorine-substituted C₁₋₆ alkyl, fluorine-substituted C₁₋₆ alkoxy, or C₁₋₆ alkyl;
R^{b6}—SO₃⁻ (BA2)
wherein
R^{b6} is fluorine-substituted C₁₋₁₀ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl; 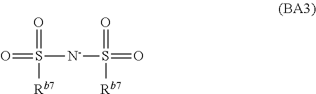
wherein
R^{b7} is each independently fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl, wherein two R^{b9} can be bonded to each other to form a fluorine-substituted heterocyclic structure; 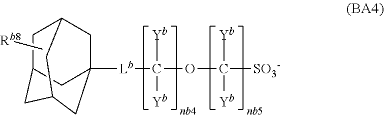
wherein
R^{b8} is hydrogen, C₁₋₆ alkyl, C₁₋₆ alkoxy or hydroxy,
L^{b2} is methylene, ethylene, carbonyl, oxy or carbonyloxy,
Y^{b} is each independently hydrogen or fluorine,
nb4 is an integer of 0 to 10, and
nb5 is an integer of 0 to 21.

8. The composition according to claim 1, wherein the solvent (C) is selected from the group consisting of propylene glycol monomethyl ether, propylene glycol monomethyl ether acetate, ethyl lactate, n-butyl acetate, n-butyl ether, 2-heptanone, cyclohexanone, and any combination thereof.

9. The composition according to claim 1, further comprising a basic compound (D) selected from the group consisting of ammonia, C₁₋₁₆ primary aliphatic amine, C₂₋₃₂ secondary aliphatic amine, C₃₋₄₈ tertiary aliphatic amine, C₆₋₃₀ aromatic amine, C₅₋₃₀ heterocyclic amine, and any combination thereof.

10. The composition according to claim 9, wherein the content of the basic compound (D) is 0.01 to 5 mass parts with respect to 100 mass parts of the polymer (A).

11. The composition according to claim 1, further comprising a surfactant (E) at a concentration of 0.005 to 1 mass parts with respect to 100 mass parts of the polymer (A).

12. The composition according to claim 1, further comprising a dye (F) at a concentration of up to 0.5 mass parts with respect to 100 parts mass parts of the polymer (A).

13. The composition according to claim 1, further comprising an additive (G) selected from the group consisting of a surface smoothing agent, a plasticizer, a contrast enhancer, an acid, a radical generator, a substrate adhesion enhancer, an antifoaming agent, and any combination thereof.

14. The composition according to claim 13, wherein the additive (G) is included at a concentration of 0 to 5 mass parts with respect to 100 mass parts of the polymer (A).

15. The composition according to claim 1, wherein the polymer (A) contains a further repeating unit other than the repeating units represented by the formulae (A-1) to (A-4), wherein the content of the further repeating unit contained in the polymer (A) is 0 to 10 mass parts with respect to 100 mass parts of the polymer (A).

16. The composition according to claim 15, wherein the further repeating unit comprises arylcarbonyl.

17. The composition according to claim 1, further comprising salicylic acid at a concentration of 0 to 0.005 mass parts with respect to 100 mass parts of the polymer (A).

18. The composition according to claim 1, wherein
the content of the polymer (A) is 10 to 40 mass % based on the composition,
the content of the photoacid generator (B) is 0.3 to 4 mass parts, preferably 0.4 to 2 mass parts, with respect to 100 mass parts of the polymer (A), and
the content of the solvent (C) is 50 to 90 mass % based on the composition.

19. A method for manufacturing a processed substrate, comprising the following steps:
manufacturing a resist pattern using the composition according to claim 1; and
performing an ion implantation using the resist pattern as a mask, or
processing the underlayer of the resist pattern using the resist pattern as a mask to form a underlayer pattern, and performing an ion implantation using the underlayer pattern as a mask.

20. A method for manufacturing a device comprising the method according to claim 15, and further comprising the step of:
forming wiring on the processed substrate.
